(19) United States
(12) Patent Application Publication
(10) Pub. No.: US 2025/0168992 A1
(43) Pub. Date: May 22, 2025

(54) SYSTEM FOR AND METHOD OF MANUFACTURING A WORKPIECE LAYER AND A COVER LAYER

(71) Applicant: Manaflex, LLC, Waikoloa, HI (US)

(72) Inventors: Robert C. Lane, Las Vegas, NV (US); Augusto E. Barton, Pinecrest, FL (US); Yifei Liu, Toronto (CA)

(21) Appl. No.: 18/953,410

(22) Filed: Nov. 20, 2024

Related U.S. Application Data
(60) Provisional application No. 63/602,014, filed on Nov. 22, 2023.

(51) Int. Cl. H05K 3/46; H05K 3/00

(52) U.S. Cl. CPC H05K 3/4635; H05K 3/0029; H05K 2203/107

(57) ABSTRACT

A process and a system for manufacturing a flexible circuit, and more particularly, to a process and a system for cutting and/or ablating a material in the manufacture of a flexible circuit. A method of manufacturing a flexible circuit includes supplying a first material, supplying a second material, the second material being a cover layer for the flexible circuit, laminating the first material to the second material to form a laminated product, moving the laminated product proximate to a camera, inspecting the laminated product via the camera to identify fiducial information the second material, determining whether a cutting device needs to be repositioned based on the detected fiducial information, and cutting the first material via the cutting device.

### CROSS-REFERENCE TO RELATED APPLICATION

The application claims priority to and the benefit of U.S. Provisional Patent Application No. 63/602,014, entitled “SYSTEM FOR AND METHOD OF MANUFACTURING A WORKPIECE LAYER AND A COVER LAYER,” filed Nov. 22, 2023, having Attorney Docket No. 4375.0002P, which is hereby incorporated in its entirety for all purposes.

### FIELD OF INVENTION

The present invention relates to a process and a system for manufacturing a flexible circuit, and more particularly, to a process and a system for cutting and/or ablating a material in the manufacture of a flexible circuit.

### BACKGROUND

Some existing manufacturing processes involve cutting one or more patterns in a layer first, and subsequently laminating the patterned layer with other layers at a later point in the manufacturing process to form a flexible circuit.

One manufacturing process for a flexible circuit utilizes a reel-to-reel system. In a reel-to-reel system, the alignment of layers for lamination is prone to have high tolerances because of the challenge and difficulty in stacking and aligning the layers in a continuous run. In addition, layer alignment on a reel-to-reel system also has a limited range of post-cutting positional adjustment because the sheets or layers require tension. In some implementations, the range of post-cutting positional adjustment is limited and very small, such as a few millimeters at the most. The high tolerance limitation hinders the yield rate and is also an obstacle to achieving finer patterns.

Some existing manufacturing processes require the use of a cover/support, such as a single use sacrificial layer opposite to the side facing a cutting device. This sacrificial layer provides a structural connection for discontinued patterns and maintains the patterns in their dedicated positions as long as needed for the process. However, this sacrificial layer is waste material as it is removed and disposed of during the manufacturing process. Since the existing process involves a sacrificial layer for support, if the existing process includes a sub-process that requires the swapping of the cover/support sacrificial layer from bottom laminating to top laminating (or vice versa), another sacrificial layer and an additional process are required which collectively make the process more complicated and the cost of material/waste higher.

Thus, there is a need for a manufacturing process that easily confirms the alignment of layers in a flexible circuit prior to any cutting of a layer. There is also a need for a manufacturing process that allows for the lamination of multiple layers prior to any cutting or ablation of one of the layers.

### SUMMARY

In one aspect of the invention, a method of manufacturing a flexible circuit comprises the steps of supplying a first material, supplying a second material, the second material being a cover layer for the flexible circuit, laminating the first material to the second material to form a laminated product, moving the laminated product proximate to a camera, inspecting the laminated product via the camera to identify fiducial information the second material, determining whether a cutting device needs to be repositioned based on the detected fiducial information, and cutting the first material via the cutting device.

In one embodiment, the method further comprises the step of repositioning the cutting device prior to the step of cutting the first material.

In another embodiment, the method further comprises the step of removing a slug of the first material after the step of cutting the first material.

In yet another embodiment, the step of the supplying a first material involves the first material being supplied from a first reel, and the method further comprises the step of collecting the laminated product after the step of cutting the first material, the step of collecting the laminated product includes collecting the laminated product on a second reel.

In another embodiment, the step of cutting the first material via the cutting device includes cutting the first material after it has been laminated to the second material, wherein the second material is not cut by the cutting device as the cutting device cuts the first material.

In another aspect of the invention, a system for manufacturing a flexible circuit comprises a source of a first material, a source of a second material, the second material being a cover layer for the flexible circuit, the second material including fiducial information, a laminating component, the laminating component being useable to laminate the first material to the second material to form a laminated product, a camera, a computing system operating software, the software analyzing an output of the camera to identify fiducial information of the second material, and a cutting device that removes a portion of the first material from the laminated product.

In one embodiment, the system includes a repositioning mechanism that is connected to the cutting device, the repositioning mechanism being operable by the software to move the cutting device to a particular position based on the fiducial information of the second material that is detected.

In another embodiment, the system includes a slug removal mechanism that is used to remove a slug of the first material after the first material is cut.

In yet another embodiment, the source of a first material includes the first material being located on a first reel, and the laminated product is collected on a second reel after the portion of the first material is removed by the cutting device from the laminated product.

In one aspect of the disclosure, a method of manufacturing a flexible circuit comprises the steps of providing a first material, providing a second material, the second material being a cover layer, laminating the second material to the first material to form a laminated product, and cutting the first material.

In one embodiment, the step of cutting the first material includes using a laser to ablate a portion of the first material. In another embodiment, a slug of the first material is peeled out with a portion of the second material. In another embodiment, the step of laminating includes laminating the second material to the first material from the top. In another embodiment, the second material is a patterned polyester (PET) layer. In another embodiment, the second material is an unpatterned PET layer.

In another embodiment, the method further comprises the step of removing the second material by either cutting from a top and from a bottom of the laminated product or rastering an area of the second material.

In yet another embodiment, the method further comprises the step of performing a sacrificial cut to remove a slug.

In another embodiment, the method further comprises the steps of using a laser to cut or raster an area of the second material, and using a sacrificial layer to remove a slug of the second material and a slug of the first material if the slug of the first material is aligned with the slug of the second material.

In another aspect of this disclosure, a method of manufacturing a flexible circuit comprises the steps of providing a first material, the first material being a workpiece metal layer, the first material having expected slug regions as a result of cutting of the first material, and welding a sacrificial metal layer proximate to the expected slug regions prior to the cutting of the first material.

In one embodiment, the method further comprises the steps of using a laser to ablate a portion of the first material and a portion of the sacrificial metal layer, and peeling out a slug of the first material and the portion of the sacrificial metal layer proximate to the slug of the first material.

In another embodiment, the method further comprises the step of laminating a patterned insulation layer to the first material, wherein the patterned insulation layer is one of a single-sided insulation layer or a double-sided insulation layer.

In another aspect of this disclosure, a method of manufacturing a flexible circuit comprises the steps of providing a metal layer, cutting portions of the metal layer to remove slugs from the metal layer, the metal layer being formed as a pattern that includes one or more tie bars that maintain portions of the metal layer pattern together, and laminating an insulation layer to the metal layer pattern, wherein the insulation layer is either patterned or unpatterned.

In one embodiment, the one or more tie bars are located over the insulation layer. In another embodiment, the method further comprises the step of ablating the one or more tie bars either by cutting any unwanted sections or by vaporizing the one or more tie bars. In another embodiment, the method further comprises the step of laminating a sacrificial layer to the insulation layer. In another embodiment, the method further comprises the step of removing slugs of the sacrificial layer and the tie bars.

In another aspect of this disclosure, a method of manufacturing a flexible circuit comprises the steps of providing a metal layer, cutting portions of the metal layer into a pattern that includes one or more tie bars that maintain portions of the metal layer together, laminating an insulative material to the metal layer, and cutting the insulative material by either a vector cut process or a raster process.

In one embodiment, a slug of the insulative material and a slug of the metal layer are removed by breaking the one or more tie bars. In another embodiment, the insulative material includes a sacrificial portion and a thermal set portion, and an adhesion force of the sacrificial portion and the thermal set portion breaks the one or more tie bars.

In another aspect of this disclosure, a method of manufacturing a flexible circuit comprises the steps of providing a metal layer, cutting portions of the metal layer into a pattern that includes one or more tie bars that maintain portions of the metal layer together, providing an insulative material, cutting the insulative material, and removing a slug of the insulative material after the step of cutting.

In one embodiment, the method further comprises the step of laminating the insulative material to the metal layer after the slug of the insulative material has been removed. In another embodiment, the method further comprises using a die, after the step of laminating, to break the one or more tie bars. In yet another embodiment, the die is one of a male/female combination or a male and air combination.

In another aspect of this disclosure, a method of manufacturing a flexible circuit comprises the steps of providing a first metal layer, cutting portions of the first metal layer into a pattern that includes one or more tie bars that maintain portions of the first metal layer together, providing a second metal layer, welding the second metal layer to the first metal layer at specific regions, and removing the second metal layer which results in the removal of a slug of the first metal layer welded to the second metal layer.

In one embodiment, the first metal layer has a top surface and a bottom surface, and the method further comprises the step of laminating a patterned insulator to the first metal layer after the step of removing the second metal layer, wherein the patterned insulator is laminated either to the top surface of the first metal layer or to the bottom surface of the first metal layer.

### BRIEF DESCRIPTION OF THE DRAWINGS

To complete the description and in order to provide for a better understanding of the present application, a set of drawings is provided. The drawings form an integral part of the description and illustrate embodiments of the present application, which should not be interpreted as restricting the scope of the invention, but just as examples. The drawings comprise the following figures:

FIG. 1 illustrates a schematic drawing of an embodiment of a manufacturing system for a flexible circuit board according to an aspect of this disclosure.

FIG. 2 illustrates a schematic drawing of a few elements of the manufacturing system shown in FIG. 1.

FIG. 3 illustrates an exemplary embodiment of a manufacturing process according to an aspect of this disclosure.

FIG. 4 illustrates a schematic drawing of another embodiment of a manufacturing system and process according to an aspect of this disclosure.

FIG. 5 illustrates a schematic drawing of another embodiment of a manufacturing system and process according to an aspect of this disclosure.

FIG. 6 illustrates a schematic drawing of another embodiment of a manufacturing system and process according to an aspect of this disclosure.

FIG. 7 illustrates a schematic drawing of another embodiment of a manufacturing system and process according to an aspect of this disclosure.

FIG. 8 illustrates a schematic drawing of another embodiment of a manufacturing system and process according to an aspect of this disclosure.

FIG. 9 illustrates a schematic drawing of another embodiment of a manufacturing system and process according to an aspect of this disclosure.

FIG. 10 illustrates a schematic drawing of another embodiment of a manufacturing system and process according to an aspect of this disclosure.

FIG. 11 illustrates a schematic drawing of another embodiment of a manufacturing system and process according to an aspect of this disclosure.

Like reference numerals have been used to identify like elements throughout this disclosure.

### DETAILED DESCRIPTION

The following description is not to be taken in a limiting sense but is given solely for the purpose of describing the broad principles of the invention. Embodiments of the invention will be described by way of example, with reference to the above-mentioned drawings showing elements and results according to the present invention.

In one aspect, the invention relates to a laser cutting or ablation process in a reel-to-reel manufacturing system for a flexible circuit. The process can cut and/or ablate a workpiece depending on the features of a particular pattern for the workpiece. In alternative embodiments, the manufacturing system may include a mechanism that is used for slug removal after the laser cutting process.

In another aspect of the invention, the cutting or ablation process can be performed on a pre-laminated stack of layers. In this aspect, the layers of the product stack can be laminated first before any pattern cutting occurs. The process can use one or more fiducials or fiducial information on a cover layer in the product stack to adjust the position of the cutting device for the cutting pattern. The resulting product is a more accurately aligned stack because of the use of fiducials.

In one exemplary embodiment, the workpiece is laminated to a pre-cut patterned layer as a cover layer for the workpiece. The pre-cut patterned layer is included in the product stack-up. The fiducial information on the cover layer is used as reference data to ensure the proper alignment of the patterning on the workpiece. A variety of features, including small and narrow features, can be patterned using laser ablation. For small and narrow features, no slug removal is required. Pattern features that result in large slugs can be laser cut. The large slugs can then be extracted using an additional slug removal process. The slug removal process can break the bond of lamination between the workpiece and the cover layer, which allows the slug of the workpiece to be removed.

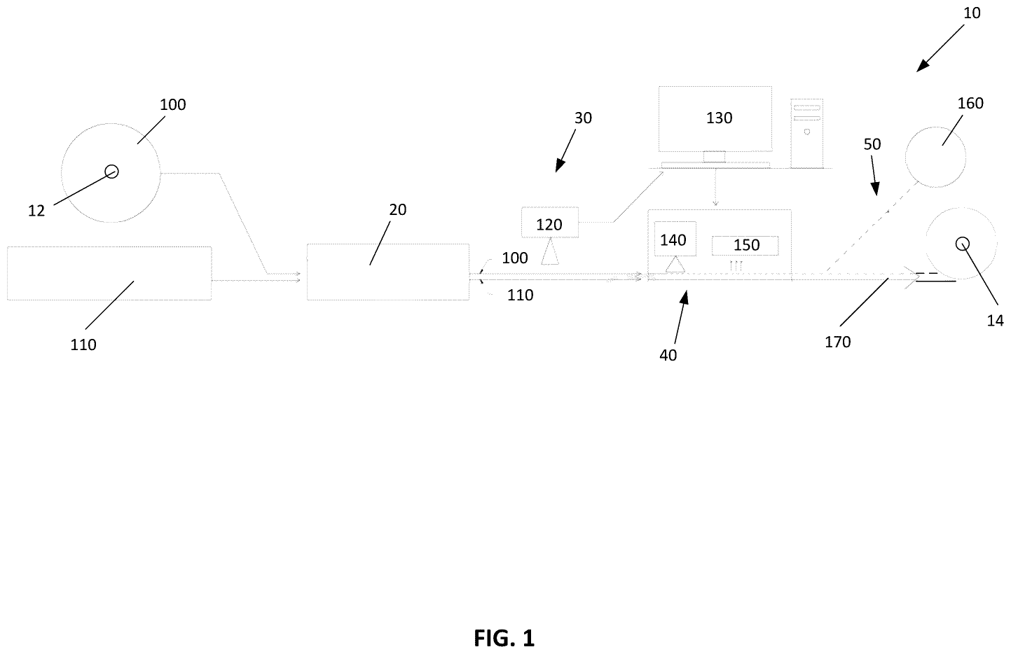

Turning initially to FIG. 1, an exemplary manufacturing system according to the invention is illustrated. This manufacturing system is used to manufacture a flexible circuit. In this embodiment, the manufacturing system 10 includes two sources of raw material that are laminated together. One source of raw material is disposed on a reel 12. This raw material is the workpiece of the flexible circuit on which cutting will occur. The workpiece can be referred to as Layer A 100, and it is supplied continuously to the manufacturing system 10. Simultaneously, another source of raw material is supplied to the manufacturing system 10 as well. This raw material is a cover layer that is laminated to the workpiece, as described below. This raw material is referred to as Layer B 110 and a single-layer material that is patterned with one or more fiducial features. In other embodiments, Layer B can be a multi-layer laminate that is patterned with one or more fiducial features.

Layer A 100 and Layer B 110 are directed or moved to the lamination process 20 in the system 10. Process 20 includes a lamination component that laminates Layer A 100 to Layer B 110. The lamination occurs on the same side of the product on which the cutting devices are located. The resulting product exiting the lamination process 20 is a laminated product that includes Layer A 100 laminated to Layer B 110. The laminated product is then transported to a position proximate to a camera 120 in the manufacturing system 10, which is where a fiducial locating process 30 is performed.

The fiducial locating process 30 utilizes the camera 120 that is oriented toward the laminated product. The camera 120 is positioned so that it can produce an output of one or more images or a video that shows a portion of laminated Layer B 110. In particular, the camera 120 is used to generate an output that captures the fiducial information on Layer B 110, which can then be used as position data.

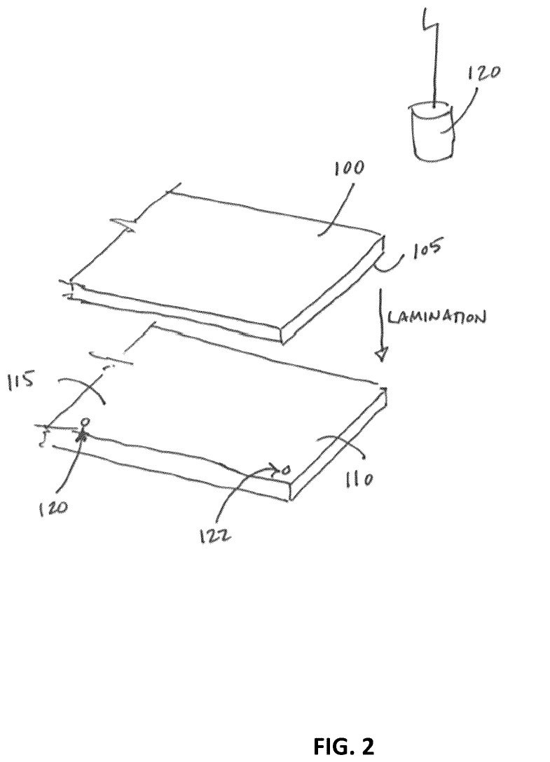

Referring to FIG. 2, a schematic perspective view of a few components is illustrated. The layers 100 and 110 are shown separated, but can be understood to be laminated together after the lamination process. The lower surface 105 of Layer A 100 is coupled to the upper surface 115 of Layer B 110. Fiducials 120 and 122 are illustrated on upper surface 115, which is oriented in the direction of the camera 120.

Referring back to FIG. 1, the camera 120 is connected to a computing device 130 that is operating a software program. While FIG. 1 illustrates an embodiment of a computing device 130, it is to be understood that in different embodiments, the computing device 130 can have any shape or configuration, and can be mobile or fixed. The software analyzes the image and/or video output from the camera 120 to identify and determine the locations of any fiducial information on Layer B 110. The software operated by computing device 130 analyzes the fiducial information, and based on that analysis, the software determines whether the cutting device needs to be shifted relative to Layer B 110. If it is determined that repositioning is needed, the computer software shifts the cutting device so that the pattern(s) it will cut are in the appropriate locations relative to Layer B 110.

The laminated product is transported to the portion 40 of the manufacturing system 10 where one or more cutting and/or ablating processes are performed. One or more cutting devices 140, such as lasers, are located in portion 40. The lasers 140 are used to cut and/or ablate either Layer A 100 (the workpiece), or both Layer A 100 (the workpiece) and Layer B 110 (the cover layer). The laminated Layer A 100 and Layer B 110 enters the laser scanning/cutting process to be laser cut/ablated using the software's adjusted pattern. Using the software's calibrated position for the lasers 140, the lasers 140 can match the cutting/ablation with positional reference to Layer B 110. The process at portion 40 can either cut or ablate, or both cut and ablate, the workpiece depending on the pattern features.

In addition, each laser 140 cuts or ablates Layer A 100 on top with a well-controlled depth of penetration that ensures the integrity of Layer B 110. In one embodiment, the cutting/ablation process 40 is limited to Layer A 100 only. In an alternative embodiment, the cutting/ablation process is performed on both Layer A 100 and Layer B 110. Layer B 110 can be cut and ablated in the same process if the product and process require such processing of Layer B 110. Portion 40 also includes a dust control component 150 which draws cutting or ablation waste product away from the laminated product.

The laser cutting or ablation process can be applied to a pre-laminated stack of layers. As described above, the product stack of Layer A 100 and Layer B 110 is laminated first before any pattern cutting. The cutting and ablating processes can use fiducials on the cover layer in the product stack to adjust the position of the cutting device. The result is a more accurate stack that is in alignment due to its ability to utilize fiducials.

It is to be appreciated that the process disclosed herein does not require a single-use sacrificial supportive layer. The workpiece is on top of the other product layers as their cover layer.

The manufacturing system 10 also includes a slug removal process 50 that results in slugs or slug material 160 being separated and removed. The slug removal process 50 is optional in different embodiments depending on the particular laser process. The finished product 170 is collected on a reel 14.

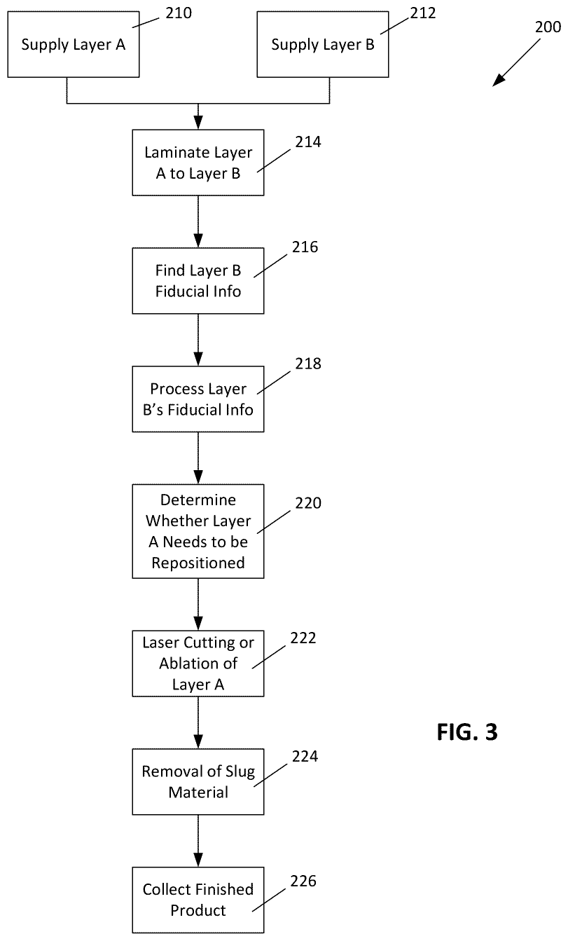

Referring to FIG. 3, an exemplary embodiment of a manufacturing process according to an aspect of the invention is illustrated. The process is used to create a product with Layers A and B, with Layer B being patterned in a separate process with a fiducial feature.

In this embodiment, the manufacturing process 200 includes several steps, which are exemplary. Initially in step 210, a first material (Layer A) is supplied continuously from a reel. Layer A is a flexible material and is referred to as a workpiece. Simultaneously, in step 212, a second material (Layer B) is supplied, and in some embodiments, Layer B can be supplied in a continuous form from a reel as well. Layer B is a flexible material, which is a different material than Layer A. Layer B is a patterned layer, and can be referred to as a cover layer.

In one embodiment of the process disclosed herein, step 214 involves the lamination of Layer A and Layer B. In particular, Layer A is laminated on top of the patterned Layer B. After the Layers A and B are laminated, the laminated product is moved proximate to a camera that captures images and/or videos of the layers, and in particular, of Layer B (see step 216). The camera is positioned so that it can pick up or capture the fiducial information on Layer B. The camera is connected to a computing device that is operating software that can identify and analyze the identified fiducial information on Layer B. The software processes the fiducial information on Layer B in step 218.

As part of the analysis of the fiducial information, the software determines whether any repositioning needs to be performed in step 220. This determination is based on the detected positions of the fiducial information, and a subsequent comparison of those detected positions relative to the information's expected positions. In step 220, if it is determined that repositioning is needed, the computer software shifts the cutting pattern to match the fiducial information of Layer B 110 by adjusting the cutting device using an adjustment mechanism.

In step 222, the cutting device (such as a laser) of the manufacturing system is used to cut and/or ablate one or more portions of Layer A that need to be removed. The amount of the Layer A that is cut or ablated depends on the desired pattern(s) for Layer A. The cutting or ablation process results in material that is removed from Layer A. Such extra material can be referred to as slug material. In step 224, the slug material is removed from the workstream and subsequently disposed. In an alternative embodiment, the manufacturing process does not include any slug material removal as set forth in step 224.

In step 226, the finished product, which includes the laminated Layer A and Layer B, both of which are flexible material layers, is collected. In one embodiment, the finished product is collected on a reel. As a result, the manufacturing process is a reel-to-reel process.

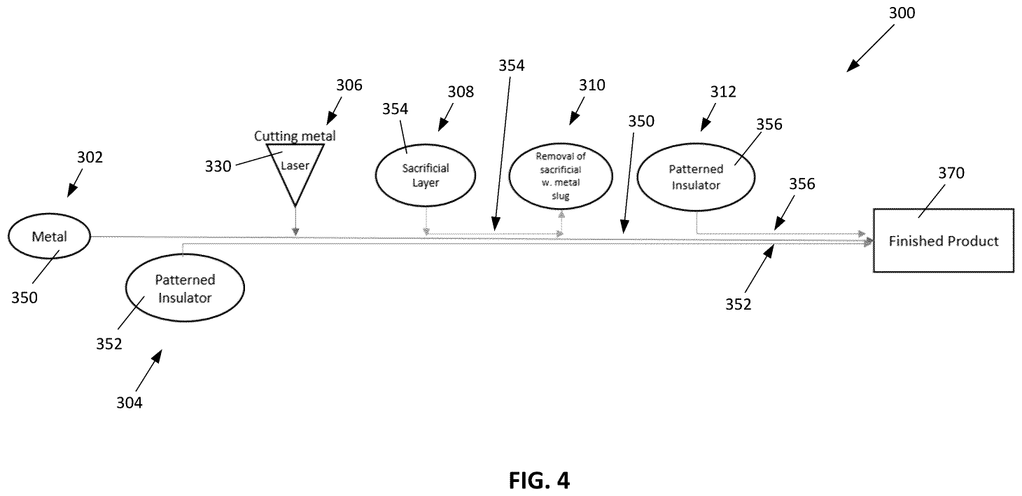

In different embodiments, the manufacturing systems and processes can have different steps, thereby creating different variants thereof. Turning to FIGS. 4-11, schematic drawings of different embodiments of manufacturing systems and processes according to this disclosure are illustrated. Each of the schematic drawings is a different embodiment in that it has a different combination of process steps, and is discussed in detail below. The processes involve different steps and different timings for certain processes, such as when insulation layers are patterned (before or after lamination to a metal layer), whether and when tie bars are utilized, when metal slugs and insulator slugs are removed, as well as the use of one or more sacrificial material layers.

The terms “insulator”, “insulator layer”, and “insulation layer” and similar variants are used interchangeably below. Also, each of the processes illustrated in FIGS. 4-11 starts with a metal layer, which can be referred to alternatively as a “workpiece metal layer”. Some of the alternative embodiments reference a sacrificial metal layer, which is different from the initial or workpiece metal layer for a process. Reference is made in the following description to relative locations of materials in terms of a “top side or “top surface” and also a “bottom side” or “bottom surface”. It is to be understood that while “top” or “bottom” are used to describe where a material is located, the alternative arrangement of “bottom” or “top” is also contemplated. Also, while the term “laser” is referenced, any suitable cutting device can be used to perform the referenced cutting and ablation, provided that the cutting device can properly and accurately make the desired cuts in one or more layers.

One alternative manufacturing system and process involves laminating a patterned polyester (PET) layer to Layer A, which is a metal layer. It is to be understood that while references are made to an insulation or insulative layer as being from a polyester (PET) material, in various implementations or embodiments, the insulation or insulative layer may be made from a different insulative material. The laser is used to ablate Layer A and peel out a slug of Layer A with a portion of a sacrificial layer. The patterned PET is laminated to Layer A from the top. Turning to FIG. 4, a schematic drawing of this manufacturing system and process is illustrated. The process 300 includes the step 302 of providing metal or a metal layer, which in this implementation is a metal layer 350 disposed on a reel. The line representing the layer of metal 350 is shown extending through the entire process to the finished product 370. Step 304 involves providing or supplying a patterned insulator 352, which can be seen in FIG. 4 as extending all of the way to be part of the finished product 370. In this implementation, the patterned insulator 352 is a PET layer that has been patterned prior to being laminated to the metal layer 350. At step 304, the patterned insulator 352 is laminated to the metal layer 350, and in particular, to the bottom surface of the metal layer 350.

After the patterned insulator 352 is laminated, step 306 relates to the cutting of the metal layer 350. In this step, a laser 330 is used to cut a portion of the metal layer 350 to form a pattern therein. The cut portion of the metal layer 350, otherwise referred to as a slug, is not removed yet.

Step 308 is when a sacrificial layer 354 of material is applied to the metal layer 350. In this embodiment, the sacrificial layer 354 is applied or coupled to the top surface of the metal layer 350. Then, in step 310, the sacrificial layer 354 is removed from the metal layer 350. When the sacrificial layer 354 is removed, a metal slug resulting from the cutting step 306 from the metal layer 350 is removed with the sacrificial layer 354.

After the metal slug and the sacrificial layer 354 are removed, at step 312, a patterned insulator 356 is laminated to the top surface of the metal layer 350. As a result, the finished product 370 from process 300 includes a patterned insulator 356 layer on top of a cut metal layer 350, and another patterned insulator 352 on the bottom of the metal layer 350.

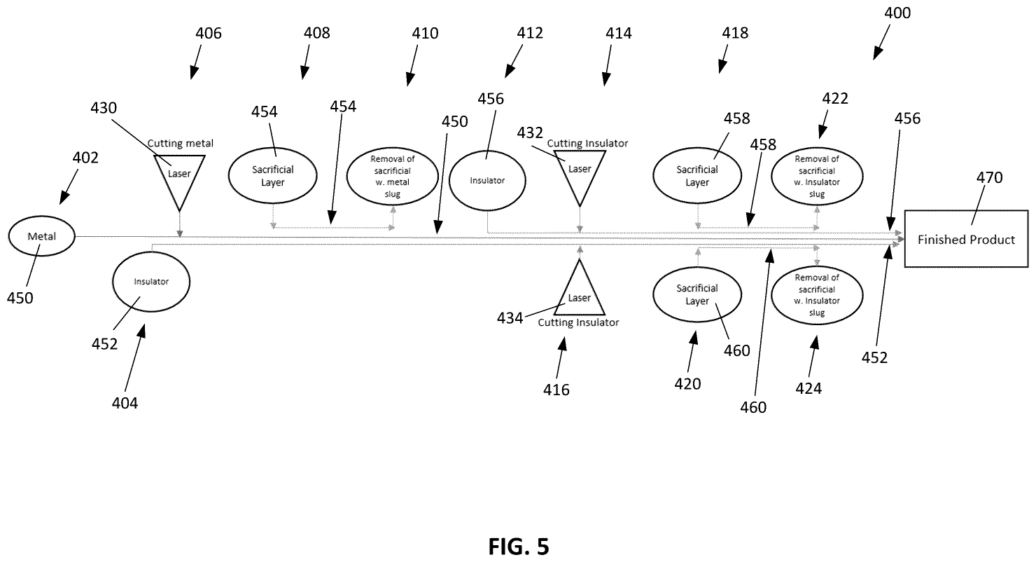

Turning to FIG. 5, a schematic drawing of another manufacturing system and process according to this disclosure is illustrated. In this process, unpatterned insulators are laminated to a metal layer, and are subsequently patterned while laminated to the metal layer. The finished product has patterned insulators on the top and on the bottom of the metal layer. The process also utilizes several different sacrificial layers.

In this process 400, the initial step 402 involves providing or supplying a metal layer 450, which can be located on a reel. The line representing the layer of metal 450 extends through the entire process to the finished product 470. Step 404 involves supplying an unpatterned insulator 452, which extends all of the way to be part of the finished product 470 as well. In this implementation, the unpatterned insulator 452 is laminated to the metal layer 450, and in particular, to the bottom surface of the metal layer 450.

After the unpatterned insulator 452 is laminated, step 406 relates to the cutting of the metal layer 450. In this step, a laser 430 is used to cut a portion of the metal layer 450 by ablating the metal layer 450 and forming a slug in the metal layer 450. The cut portion or slug 450 of the metal layer 450 is not removed at this time.

Step 408 involves coupling a sacrificial material layer 454 to the top surface of the metal layer 450. Then, in step 410, the sacrificial layer 454 is removed from the metal layer 450. When the sacrificial layer 454 is removed, a metal slug resulting from the cutting step 406 from the metal layer 450 is removed with the sacrificial layer 454. In other words, in this process 400, a sacrificial layer is used to remove the metal slug from metal layer.

After the metal slug and the sacrificial layer 454 are removed, at step 412, an unpatterned insulator 456 is laminated to the top surface of the metal layer 450. At step 414, a laser 432 is used to cut one or more particular portions of the unpatterned insulator 456 to form a pattern, thereby patterning the insulator 456 after it has been laminated to the metal layer 450. Similarly, at step 416, a laser 434 is used to cut one or more particular portions of the unpatterned insulator 452 to form a pattern, thereby patterning the insulator 452 after it has been laminated to the metal layer 450.

After insulator 456 has been cut, at step 418, another sacrificial layer 458 is coupled to the insulator 456. Similarly, after insulator 452 has been cut, at step 420, another sacrificial layer 460 is coupled to the insulator 452. At step 422, sacrificial layer 458 is removed from insulator 456, which removes with it the insulator 456 slug or slugs that result from cutting step 414. Similarly, at step 424, sacrificial layer 460 is removed from insulator 452, which removes with it the insulator 452 slug or slugs that result from cutting step 416. As a result, the finished product 470 from process 400 includes a patterned insulator 456 layer on top of a cut metal layer 450, and another patterned insulator 452 on the bottom of the metal layer 450.

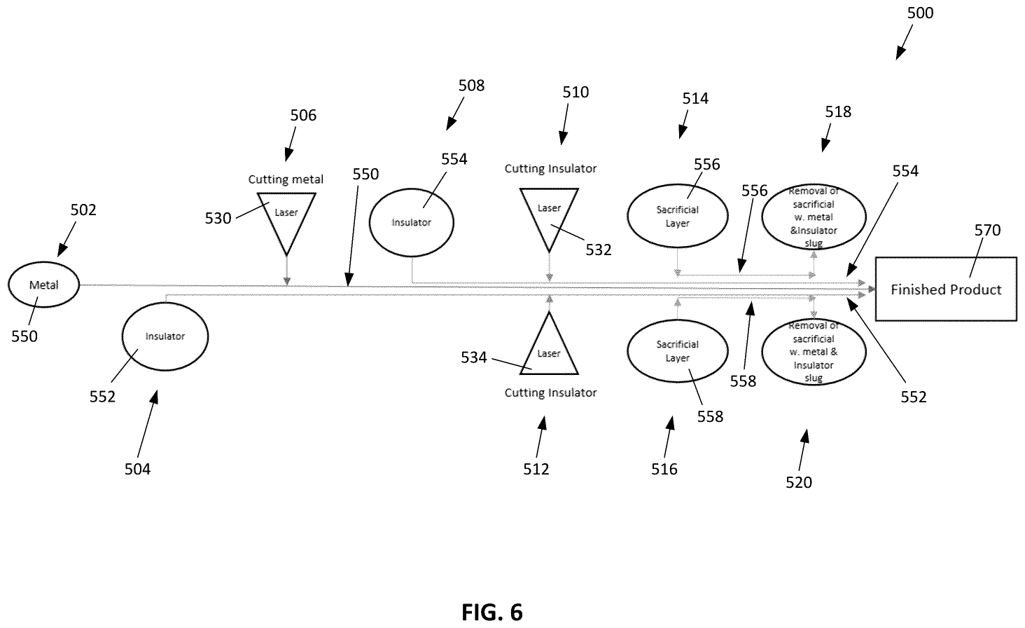

Turning to FIG. 6, a schematic drawing of another embodiment of a manufacturing system and process according to this disclosure is illustrated. In this process, unpatterned insulators are laminated to the metal layer at different points in the process, and subsequently patterned. Also, sacrificial material layers are used to remove any slugs from the metal layer and the insulator after the patterning of the insulator.

In this process 500, the initial step 502 involves providing or supplying metal 550, which can be located on a reel. The line representing the layer of metal 550 extends through the entire process to the finished product 570. Step 504 involves supplying an unpatterned insulator 552, which extends all of the way to be part of the finished product 570 as well. In this implementation, the unpatterned insulator 552 is laminated to the metal layer 550, and in particular, to the bottom surface of the metal layer 550.

After the unpatterned insulator 552 is laminated, step 506 relates to the cutting of the metal layer 550 to form a pattern. In this step, a laser 530 is used to cut a portion of the metal layer 550 by ablating the metal layer 550 and forming a slug in the metal layer 550. The cut portion or slug of the metal layer 550 is not removed at this time.

In step 508, an unpatterned insulator 554 is laminated to the top surface of the metal layer 550. At step 510, a laser 532 is used to cut and/or raster one or more particular portions of the unpatterned insulator 554 to form a pattern, thereby patterning the insulator 554 after it has been laminated to the metal layer 550. Similarly, at step 512, another laser 534 is used to cut and/or raster one or more particular portions of the unpatterned insulator 552 to form a pattern, thereby patterning the insulator 552 after it has been laminated to the metal layer 550.

Step 514 involves coupling a sacrificial layer 556 of material to the top surface of the metal layer 550. Similarly, step 516 involves coupling another sacrificial layer 558 of material to the bottom surface of the metal layer 550.

Turning to step 518, the sacrificial layer 556 is removed from the metal layer 550. When sacrificial layer 556 is removed, a slug from insulator 554 resulting from the cutting step 510, and a metal slug from the metal layer 550 resulting from the cutting step 506, if aligned with the insulator slug, are removed with sacrificial layer 556. Similarly, in step 520, sacrificial layer 558 is removed from the metal layer 550. When sacrificial layer 558 is removed, a slug from insulator 552 resulting from the cutting step 512 is removed with sacrificial layer 558. If the slug from metal layer 550 has not been removed yet, and it is aligned with the slug from insulator 552, the metal slug is also removed with the slug from insulator 552 when sacrificial layer 558 is removed. As a result, the finished product 570 from process 500 includes an insulator layer 554 that has been laminated and then patterned on top of a metal layer 550, and another insulator 552 layer that has been laminated and then patterned on the bottom of the metal layer 550.

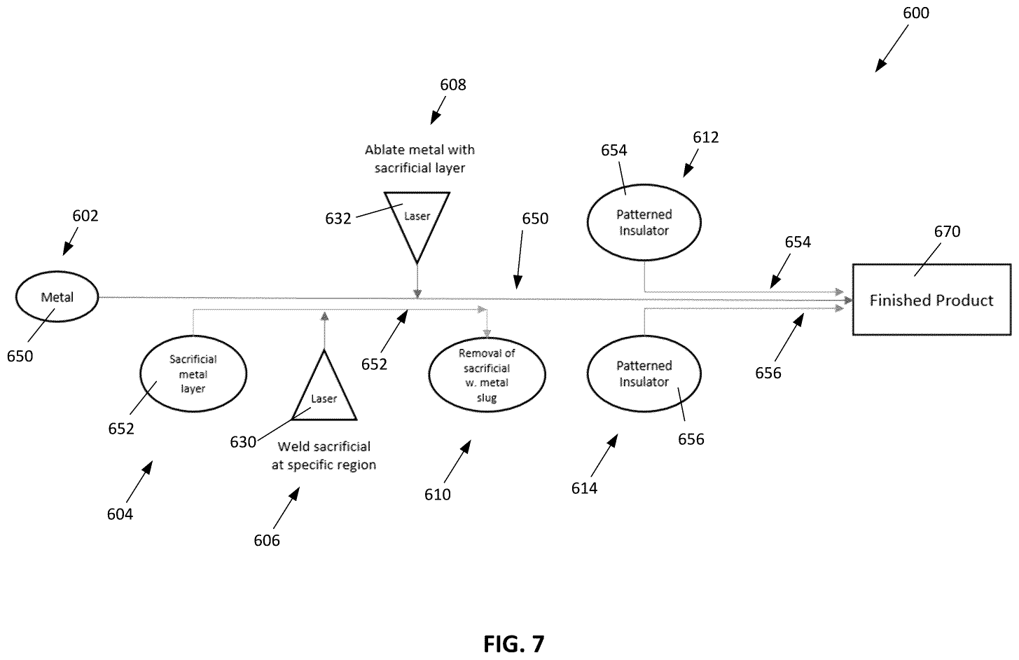

Turning to FIG. 7, a schematic drawing of another embodiment of a manufacturing system and process according to this disclosure is illustrated. In this process, a sacrificial layer that is made of metal is used early in the process. The sacrificial metal layer is used to remove the metal layer slug. After the metal slug is removed, prepatterned insulators are laminated to the metal layer.

In this process 600, the initial step 602 involves providing or supplying a metal layer 650, which can be located on a reel. The line representing the layer of metal 650 extends through the entire process to the finished product 670. Step 604 involves supplying a sacrificial metal layer 652 proximate to the workpiece metal layer 650. In this implementation, the sacrificial metal layer 652 can be positioned proximate to the bottom surface of the metal layer 650.

Step 606 relates to the welding of the sacrificial metal layer 652 at a specific region. In this step, a laser 630 is used to weld the sacrificial metal layer 652 in expected slug regions to the metal layer 650. Step 608 involves the ablation of the metal layer 650 and the sacrificial metal layer 652. In this process 600, a laser 632 is used for the ablation performed in step 608. After the ablation has occurred, step 610 is performed to remove or peel out the sacrificial metal layer 652 and the metal slug that was formed by the ablation in step 608. At this point in the process, only workpiece metal layer 650 is present.

In step 612, a patterned insulator 654 is laminated to the top surface of the metal layer 650. Similarly, at step 614, a patterned insulator 656 is laminated to the bottom surface of the metal layer 650. The patterned insulators 654 and 656 can be single or double-sided insulation layers that are laminated to the metal layer 650. As a result, the finished product 670 from process 600 includes a patterned insulator layer 654 that has been laminated on top of a metal layer 650, and another patterned insulator layer 656 that has been laminated on the bottom of the metal layer 650.

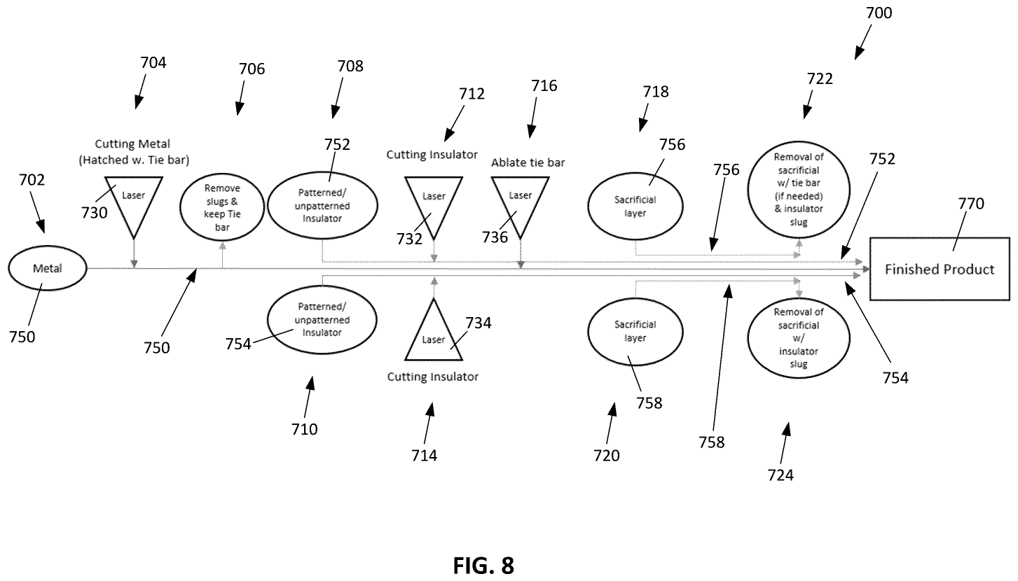

Turning to FIG. 8, a schematic drawing of another manufacturing system and process according to this disclosure is illustrated. In this process, the metal layer is cut to form one or more tie bars. Insulators that are either prepatterned or unpatterned are laminated to the metal layer, and are subsequently cut. Sacrificial material layers are used to remove any tie bars and insulator slugs. The finished product has insulators on the top and on the bottom of the metal layer.

In this process 700, the initial step 702 involves providing or supplying metal 750, which can be located on a reel. The line representing the layer of metal 750 extends through the entire process to the finished product 770. Step 704 involves cutting the metal layer 750 into a pattern that is a web with tie bars. The cutting step 704 is performed using a laser 730. In step 706, the slugs from the metal layer 750 are removed and the tie bars cut in step 704 remain. The metal pattern that was cut is kept together with the aid of the tie bars.

Turning to step 708, an unpatterned or patterned insulator 752 is laminated to the metal layer 750 on its top surface. Similarly, step 710 involves another unpatterned or patterned insulator 754 that is laminated to the metal layer 750 on its bottom surface. The tie bars are located over insulator layer 752. Step 712 is the cutting of a pattern in insulator 752 using a laser 732. Similarly, step 714 is the cutting of a pattern in insulator 754 using a laser 734. In step 716, another laser 736 is used to ablate the tie bars of the metal layer by cutting the unwanted sections. Alternatively, the tie bars can be ablated by vaporizing each of the tie bars.

Step 718 involves coupling a sacrificial layer 756 to the top surface of insulator 752. Similarly, step 720 involves coupling a sacrificial layer 758 to the bottom surface of insulator 754. Then, in step 722, the sacrificial layer 756 is removed from insulator 752. The removal of the sacrificial layer 756 also removes the tie bars, if needed, and any slug material from insulator 752. The tie bars are removed with the sacrificial layer 756 because the tie bars are located on the outer surface of the insulator 752. Similarly, in step 724, the sacrificial layer 758 is removed from insulator 754. The removal of sacrificial layer 758 also removes any slug material from insulator 754. As a result, the finished product 770 from process 700 includes an insulator 752 on top of a metal layer 750, and another insulator 754 on the bottom of the metal layer 750.

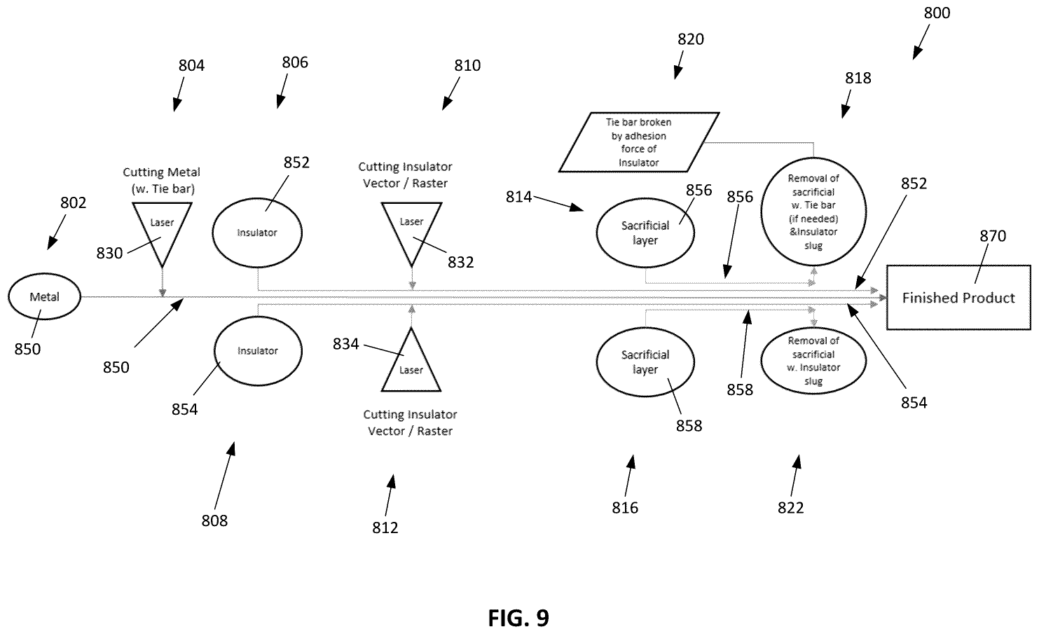

Turning to FIG. 9, another embodiment of a manufacturing system and process according to this disclosure is illustrated. In this process, the finished product has insulators on the top and on the bottom of the metal layer.

In this process 800, the initial step 802 involves providing or supplying metal 850, which can be located on a reel. The line representing the layer of metal 850 extends through the entire process to the finished product 870. Step 804 involves cutting the metal layer 850 into a pattern that is a web with one or more tie bars. The cutting step 804 is performed using a laser 830. The slug from the metal layer 850 is not removed at this time. The metal pattern that was cut is kept together with the aid of the tie bar or tie bars.

Turning to step 806, an unpatterned or patterned insulator 852 is laminated to the metal layer 850 on its top surface. Similarly, step 808 involves another unpatterned or patterned insulator 854 that is laminated to the metal layer 850 on its bottom surface. Step 810 is the cutting of a pattern in insulator 852 using a laser 832. The insulator 852 is either vector cut or rastered. Similarly, step 812 is the cutting of a pattern in insulator 854 using a laser 834. Like insulator 852, insulator 854 is either vector cut or rastered.

Step 814 involves coupling a sacrificial layer 856 to the top surface of insulator 852. Similarly, step 816 involves coupling a sacrificial layer 858 to the bottom surface of insulator 854. Then, in step 818, the sacrificial layer 856 is removed from insulator 852. The remaining insulator slug and the metal layer slug are removed by breaking the tie bars. The adhesion force of the PET sacrificial and the PET thermal set breaks the tie bars. The tie bars are removed with the sacrificial layer 856 because the tie bars are located on the outer surface of the insulator 852. As noted in FIG. 9, in step 820, the tie bar is broken by the adhesion force of the insulator 852. In step 822, the sacrificial layer 858 is removed from insulator 854. The removal of sacrificial layer 858 also removes any slug material from insulator 854. As a result, the finished product 870 from process 800 includes an insulator 852 on top of a metal layer 850, and another insulator 854 on the bottom of the metal layer 850.

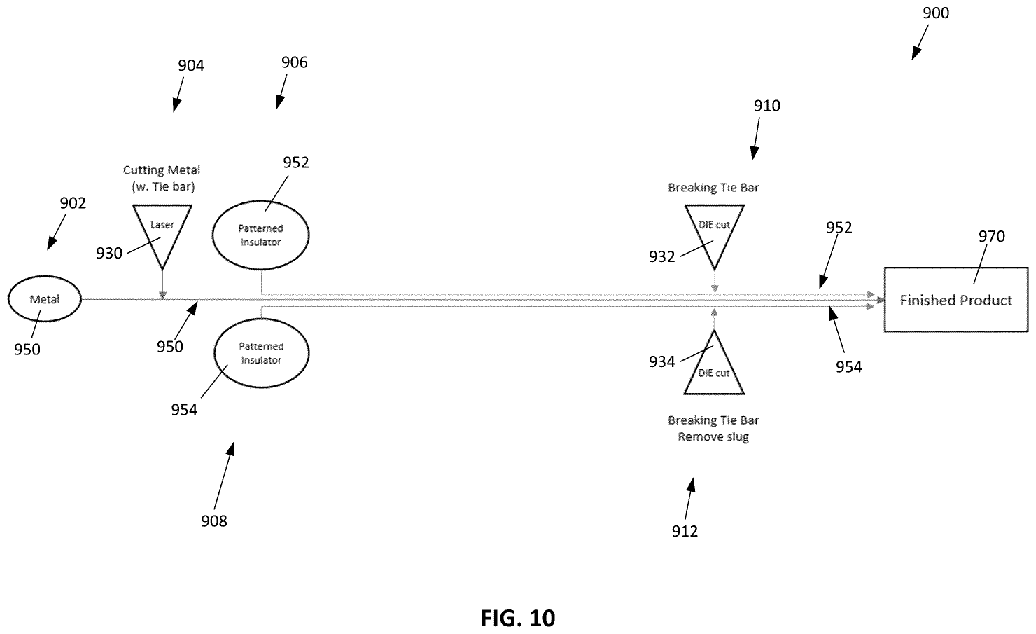

Turning to FIG. 10, another embodiment of a manufacturing system and process according to this disclosure is illustrated. In this process, the metal layer is cut before the prepatterned insulators are laminated to the metal layer. The finished product has insulators on the top and on the bottom of the metal layer.

In this process 900, the initial step 902 involves providing or supplying a metal layer 950, which can be located on a reel. The line representing the layer of metal 950 extends through the entire process to the finished product 970. Step 904 involves cutting the metal layer 950 into a pattern that is a web with one or more tie bars. The cutting step 904 is performed using a laser 930. The slug from the metal layer 950 is removed. The metal pattern that was cut is kept together with the aid of the tie bar or tie bars.

Turning to step 906, a patterned insulator 952 is laminated to the metal layer 950 on its top surface. Similarly, step 908 involves another patterned insulator 954 that is laminated to the metal layer 950 on its bottom surface.

Steps 910 and 912 are the breaking of the tie bar or tie bars by using a die cut system that includes die components 932 and 934. In step 910, insulator 952 is cut using die component 932. Similarly, in step 912, insulator 954 is cut using die component 934. The cutting die components 932 and 934 can be a male/female combination, a male and air combination, or other die structure. When the tie bar or tie bars are broken, any remaining slugs can be removed. The finished product 970 from process 900 includes an insulator 952 on top of a metal layer 950, and another insulator 954 on the bottom of the metal layer 950.

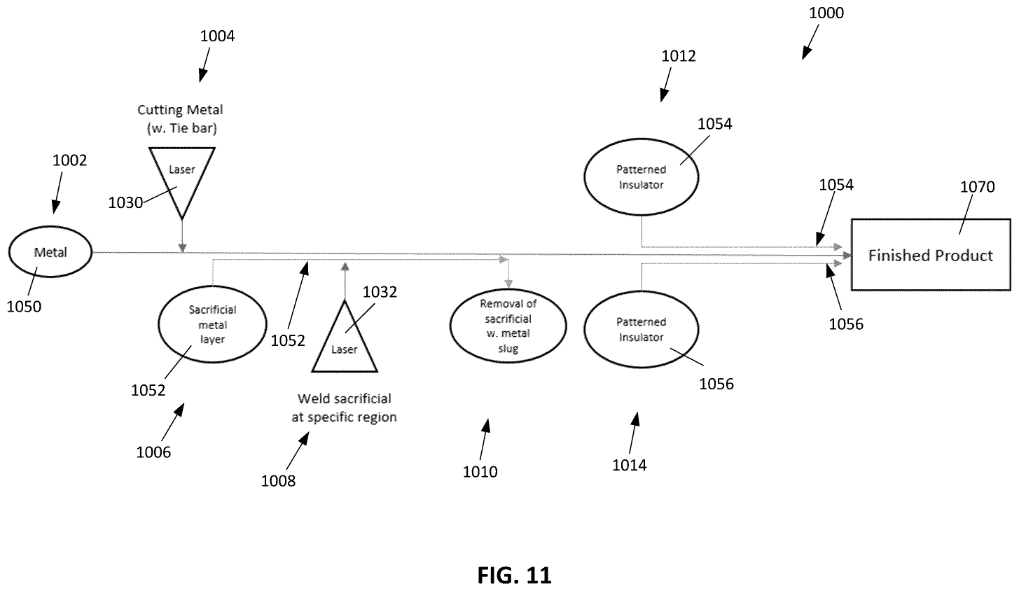

Turning to FIG. 11, a schematic drawing of another embodiment of a manufacturing system and process according to this disclosure is illustrated. In this process, a sacrificial metal layer is used to remove a slug from the metal layer. Prepatterned insulators are laminated to the metal layer after the metal layer is prepared.

In this process 1000, the initial step 1002 involves providing or supplying a metal layer 1050, which can be located on a reel. The line representing the layer of metal 1050 extends through the entire process to the finished product 1070. Step 1004 involves cutting the metal layer 1050 into a pattern that is a web with one or more tie bars. The cutting step 1004 is performed using a laser 1030. The slug from the metal layer 1050 is not removed at this time. The metal pattern that was cut is kept together with the aid of the tie bar or tie bars.

Step 1006 involves supplying a sacrificial metal layer 1052 proximate to the workpiece metal layer 1050. In this implementation, the sacrificial metal layer 1052 can be positioned proximate to the bottom surface of the metal layer 1050.

Step 1008 relates to the welding of the sacrificial metal layer 1052 at a specific region. In this step, a laser 1032 is used to weld the sacrificial metal layer 1052 in expected slug regions to the metal layer 1050. Step 1010 is performed to remove or peel out the sacrificial metal layer 1052 and the metal slug that was formed by the ablation in step 1008. At this point in the process, only workpiece metal layer 1050 is present.

In step 1012, a patterned insulator 1054 is laminated to the top surface of the metal layer 1050. Similarly, at step 1014, a patterned insulator 1056 is laminated to the bottom surface of the metal layer 1050. The patterned insulators 1054 and 1056 can be single or double-sided insulation layers that are laminated to the metal layer 1050. As a result, the finished product 1070 from process 1000 includes a patterned insulator layer 1054 on top of metal layer 1050, and another patterned insulator layer 1056 located on the bottom of the metal layer 1050.

One advantage of the manufacturing processes and systems described above is that there is better tolerance control. Since the workpiece layer can be patterned after the layers are laminated, the patterned layer can be reference-cut following the fiducial of any lower layers. The result is a much better tolerance for the patterned layer in the product stack up assembly.

Another advantage of the manufacturing processes and systems is that the patterned layer is laminated with other product layers before the ablation process. A sacrificial layer is not needed because the other laminated layers can provide the structural strength needed for the patterns. Laser ablation processes can control the ablation depth to prevent laser damage to the other layers.

While the invention has been illustrated and described in detail and with reference to specific embodiments thereof, it is nevertheless not intended to be limited to the details shown, since it will be apparent that various modifications and structural changes may be made therein without departing from the scope of the inventions and within the scope and range of equivalents of the claims. In addition, various features from one of the embodiments may be incorporated into another of the embodiments. Accordingly, it is appropriate that the appended claims be construed broadly and in a manner consistent with the scope of the disclosure as set forth in the following claims.

Similarly, it is intended that the present invention cover the modifications and variations of this invention that come within the scope of the appended claims and their equivalents. For example, it is to be understood that terms such as “left,” “right,” “top,” “bottom,” “front,” “rear,” “side,” “height,” “length,” “width,” “upper,” “lower,” “interior,” “exterior,” “inner,” “outer” and the like as may be used herein, merely describe points of reference and do not limit the present invention to any particular orientation or configuration. Further, the term “exemplary” is used herein to describe an example or illustration. Any embodiment described herein as exemplary is not to be construed as a preferred or advantageous embodiment, but rather as one example or illustration of a possible embodiment of the invention.

Finally, when used herein, the term “comprises” and its derivations (such as “comprising”, etc.) should not be understood in an excluding sense, that is, these terms should not be interpreted as excluding the possibility that what is described and defined may include further elements, steps, etc. Meanwhile, when used herein, the term “approximately” and terms of its family (such as “approximate,” etc.) should be understood as indicating values very near to those which accompany the aforementioned term. That is to say, a deviation within reasonable limits from an exact value should be accepted, because a skilled person in the art will understand that such a deviation from the values indicated is inevitable due to measurement inaccuracies, etc. The same applies to the terms “about” and “around” and “substantially.

1. A method of manufacturing a flexible circuit, the method comprising the steps of:
providing a first material;
providing a second material, the second material being a cover layer;
laminating the second material to the first material to form a laminated product; and
cutting the first material.

2. The method of claim 1, wherein the step of cutting the first material includes using a laser to ablate a portion of the first material.

3. The method of claim 2, wherein a slug of the first material is peeled out with a portion of the second material.

4. The method of claim 1, wherein the step of laminating includes laminating the second material to the first material from the top.

5. The method of claim 4, wherein the second material is a patterned polyester (PET) layer.

6. The method of claim 4, wherein the second material is an unpatterned PET layer.

7. The method of claim 1, further comprising the step of:
removing the second material by either cutting from a top and from a bottom of the laminated product or rastering an area of the second material.

8. The method of claim 7, further comprising the step of:
performing a sacrificial cut to remove a slug.

9. The method of claim 1, wherein further comprising the steps of:
using a laser to cut or raster an area of the second material; and
using a sacrificial layer to remove a slug of the second material and a slug of the first material if the slug of the first material is aligned with the slug of the second material.

10. A method of manufacturing a flexible circuit, the method comprising the steps of:
providing a first material, the first material being a workpiece metal layer, the first material having expected slug regions as a result of cutting of the first material; and
welding a sacrificial metal layer proximate to the expected slug regions prior to the cutting of the first material.

11. The method of claim 10, further comprising the steps of:
using a laser to ablate a portion of the first material and a portion of the sacrificial metal layer; and
peeling out a slug of the first material and the portion of the sacrificial metal layer proximate to the slug of the first material.

12. The method of claim 11, further comprising the step of:
laminating a patterned insulation layer to the first material, wherein the patterned insulation layer is one of a single-sided insulation layer or a double-sided insulation layer.

13. A method of manufacturing a flexible circuit, the method comprising the steps of:
providing a metal layer;
cutting portions of the metal layer to remove slugs from the metal layer, the metal layer being formed as a pattern that includes one or more tie bars that maintain portions of the metal layer pattern together; and
laminating an insulation layer to the metal layer pattern, wherein the insulation layer is either patterned or unpatterned.

14. The method of claim 13, wherein the one or more tie bars are located over the insulation layer.

15. The method of claim 14, further comprising the step of:
ablating the one or more tie bars either by cutting any unwanted sections or by vaporizing the one or more tie bars.

16. The method of claim 14, further comprising the step of:
laminating a sacrificial layer to the insulation layer.

17. The method of claim 16, further comprising the step of:
removing slugs of the sacrificial layer and the tie bars.

18.-26. (canceled)

27. The method of claim 13, wherein a slug of the insulation layer and a slug of the metal layer are removed by breaking the one or more tie bars.

28. The method of claim 27, wherein the insulation layer includes a sacrificial portion and a thermal set portion, and an adhesion force of the sacrificial portion and the thermal set portion breaks the one or more tie bars.
